(19) United States
(12) Patent Application Publication
(10) Pub. No.: US 2014/0049916 A1
(43) Pub. Date: Feb. 20, 2014

(54) HEAT DISSIPATION FAN AND POWER DEVICE

(71) Applicant: Zhifei CHEN, Dongguan (CN)

(72) Inventor: Zhifei CHEN, Dongguan (CN)

(73) Assignee: DELTA ELECTRONICS POWER (DONG GUAN) CO., LTD., DONGGUAN (CN)

(21) Appl. No.: 13/619,966

(22) Filed: Sep. 14, 2012

(30) Foreign Application Priority Data
Aug. 14, 2012 (CN) 201210287414.8

(51) Int. Cl. H05K 7/20

(52) U.S. Cl. 361/695

(57) ABSTRACT

A heat dissipation fan and a power device are provided. The heat dissipation fan includes a frame, a fan circuit board, a fan motor, multiple fan blades and a thermistor. The frame has an air inlet side and an air outlet side, and forms a base hoard on the middle of the middle of the air outlet side. The fan circuit board is mounted on the base board. The fan motor is mounted on the base board and electrically connected to the fan circuit board. The thermistor is disposed on the fan circuit board or the frame to provide a temperature-sensing function for the heat dissipation fan. The heat dissipation fan is applied to the power device to save the internal space of the power device, and can provide reliable temperature information for the power device to improve the working quality of the power device.

### BACKGROUND OF THE INVENTION

1. Field of the Invention

The present invention relates to a heat dissipation fan and a power device, and more particularly to a heat dissipation fan disposing a thermistor and to a power device having the heat dissipation fan.

2. Description of the Background Art

At present, a heat dissipation fan has been a necessary device of various electronic equipments and electronic systems. For example, a computer, a power device of a server, a computer case and some electronic products all need to dispose the heat dissipation fan for helping these devices dissipate the heat. Moreover, it also needs to mount an NTC thermistor in the power device to sense the temperature, thereby realizing the object of precisely controlling the power device.

Please refer to FIG. 1, which shows an internal structure of a conventional power device 9 and an airflow direction A in the internal of the power device 9, the conventional power device 9 has an air inlet opening 90 and an air outlet opening 91. A thermistor 92 is mounted on a control circuit board 93 of the power device 9 and near the air outlet opening 90, and is used to sense the nearby environment temperature of the air inlet opening 90 and then transmit the sensed temperature signal to the control circuit board 93. Then the control circuit board 93 may determine to start or close a heat dissipation fan 94 according to the temperature signal, and even can adjust the rotation rate of the heat dissipation fan 94 according to the temperature signal. The heat dissipation fan 94 is mounted on the air outlet opening 91 of the power device 9, and can rotate at a certain rate to form airflow to take away the hot air in the internal of the power device 9. The cold air enters into the power device 9 from the air inlet opening 90.

Presently, in a new type of the computer, because the power device 9 is in a positive pressure air system, the airflow direction A in the power device 9 needs to be changed. But the structure arrangement of the convention power device 9 only can adopt the airflow direction A shown as FIG. 1 to realize the exact temperature control. But if the airflow direction A changes, the temperature can not be exactly controlled. Specifically, in the new type of the computer, the original air inlet opening 90 of the conventional power device 9 changes to be a new air outlet opening, and the original air outlet opening 91 changes to be a new air inlet opening. Now because the heat dissipation fan 94 located at the original air outlet opening 91 only has a single function of providing airflow, and does not have the function of sensing temperature. The thermistor 92 at the original air inlet opening 90 can not timely sense the temperature at the new air inlet opening, so the power device 9 can not realize the exact temperature control.

Thus, in the new sort of computer, the thermistor 92 should not be disposed at the original air inlet opening 90, but be disposed near the new air inlet opening, thereby exactly sensing the nearby environment temperature of the new air inlet opening.

According to the conventional design mode, the design solution of disposing the thermistor 92 near the new air inlet opening (original air outlet opening 91) has two ways as following:

1. Redesigning the control circuit board 93 in the power device 9, wherein the thermistor 92 is directly mounted or inserted onto the other control circuit board 96 near the heat dissipation fan 94, But this way needs to substantially change the circuit of the circuit boards 93 and 96, so it is not an effective and economic way.

2. Fixing the thermistor 92 to a certain component near the new air inlet opening by a bolt, a nut, a holder or other fixtures, and then transmitting the signal of the thermistor 92 back to the original control circuit board 93 by an electric wire connection mode. But the main defect of this way is that the thermistor 92, the fixtures and the wire likely prevent the airflow passage and increase the airflow impedance, so result in decreasing the airflow volume and affecting the whole heat dissipation effect.

Hence, it is necessary to provide a new heat dissipation fan, which not only has a function of providing airflow, but also has a function of sensing temperature, to overcome the defect existing in the background art.

### BRIEF SUMMARY OF THE INVENTION

One object of the present invention is to provide a heat dissipation fan, which disposes a thermistor for timely sensing the environment temperature around the heat dissipation fan.

Another object of the present invention is to provide a power device, in which a heat dissipation fan is mounted, wherein the heat dissipation fan has functions of providing airflow and sensing temperature, can save the internal space of the power device, and can provide the reliable temperature information to improve the working quality of the power device.

Other objects and advantages of the present invention may be further understood from the technical features disclosed by the present invention.

To achieve the aforementioned objects or other objects of the present invention, the present invention adopts the following technical solution: a heat dissipation fan, which is mounted at an air inlet opening of a power device, comprises: a frame having an air inlet side and an air outlet side and forming a base board on the middle of the air outlet side; a fan circuit board being mounted on the base board of the frame; a fan motor being mounted on the base board of the frame and being electrically connected to the fan circuit board; multiple fan blades being mounted on the fan motor; and a thermistor.

To achieve the aforementioned objects or other objects of the present invention, the present invention also adopts the following technical solution: a power device comprises: an outer case having one air inlet opening and multiple air outlet openings; a heat dissipation fan being mounted in the outer case and located at the air inlet opening of the outer case; a control circuit board being mounted in the outer case; and multiple electronic components being mounted in the outer case. Wherein the heat dissipation fan comprises: a frame having an air inlet side and an air outlet side and forming a base board on the middle of the air outlet side; a fan circuit board being mounted on the base board of the frame; a fan motor being mounted on the base board of the frame and being electrically connected to the fan circuit board; multiple fan blades being mounted on the fan motor; and a thermistor being capable of providing the nearby temperature information of the air inlet opening for the control circuit board.

Comparing with the background art, the heat dissipation fan of the present invention disposes the thermistor, so the heat dissipation fan of the present invention not only has a function of providing airflow, but also has a function of sensing temperature. The heat dissipation fan is applied to the power device to save the internal space of the power device. The alteration of the airflow direction and the mounting position of the heat dissipation fan are helped to improve the fan service life, and may provide reliable temperature information to improve the working quality of the power device.

For more clearly and easily understanding above content of the present invention, the following text will take a preferred embodiment with reference to the accompanying drawings for detail description as follows.

### BRIEF DESCRIPTION OF THE DRAWINGS

FIG. 1 is an internal structure schematic view of a conventional power device, and shows an airflow direction in the conventional power device;

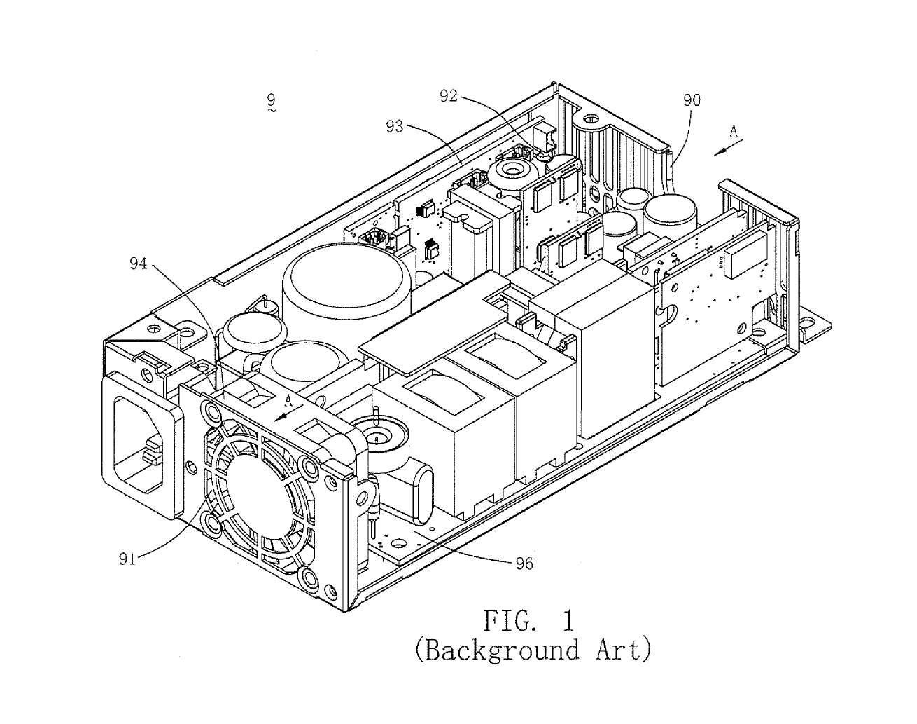

FIG. 2 is an internal structure schematic view of one embodiment of a power device of the present invention, and shows an airflow direction in the power device;

FIG. 3 is a structure schematic view of a first embodiment of a heat dissipation fan of the present invention;

FIG. 4 is a plan structure schematic view of the heat dissipation fan of the present invention shown in FIG. 3;

FIG. 5 is a circuit diagram of a thermistor being disposed on a fan circuit board in the first embodiment of the heat dissipation fan of the present invention

FIG. 6 is a plan structure schematic view of another embodiment of the heat dissipation fan of the present invention, wherein the thermistor is mounted on a base board of a frame; and

FIG. 7 is a plan structure schematic view of another one embodiment of the heat dissipation fan of the present invention, wherein the thermistor is mounted on a support spoke of the frame.

The reference numerals in the drawings are described as follows:

1 power device

10 outer case

20 heat dissipation fan

30 control circuit board

31 connector

40 electronic component

12 air inlet opening

14 air outlet opening

21 frame

210 air inlet side

212 air outlet side

214 base board

216 support rib

22 fan circuit board

23 fan motor

24 fan blade

25 thermistor

250 grounding point

251 temperature signal-outputting point 251

26 temperature signal-outputting wire

27 power signal-outputting wire

### DETAILED DESCRIPTION OF THE PREFERRED EMBODIMENTS

The following description of every embodiment with reference to the accompanying drawings is used to exemplify a specific embodiment, which may be carried out in the present invention. Directional terms mentioned in the present invention, such as “top”, “bottom”, “front”, “back”, “left”, “right”, “inside”, “outside”, “side” etc., are only used with reference to the orientation of the accompanying drawings. Therefore, the used directional terms are intended to illustrate, but not to limit, the present invention.

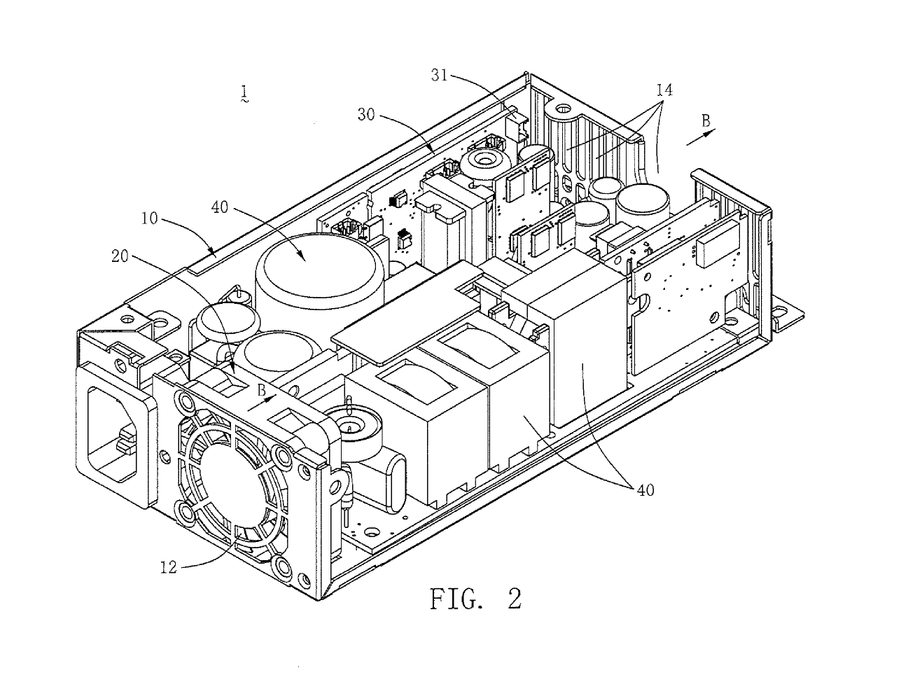

Please refer to FIG. 2, which shows an internal structure of one embodiment of a power device 1 of the present invention and an airflow direction B in the power device 1. The power device 1 of the present invention comprises an outer case 10, a heat dissipation fan 20 mounted in the outer case 10, a control circuit board 30 mounted in the outer case 10, and multiple electronic components 40. The outer case 10 has one air inlet opening 12 and multiple air outlet openings 14. The heat dissipation fan 20 is located at the air inlet opening 12 of the outer case 20, and can rotate at a certain rate to suck the outside cold air into the internal of the power device 1 for cooling the power device 1 and exhaust the hot air from the multiple air outlet openings 14. The heat dissipation fan 20 of the power device 1 of the present invention not only has a function of providing airflow, but also has a function of sensing temperature. The heat dissipation fan 20 can provide exact temperature information of the air inlet opening 12. The following text will detail describe the specific structure of the heat dissipation fan 20 of the present invention.

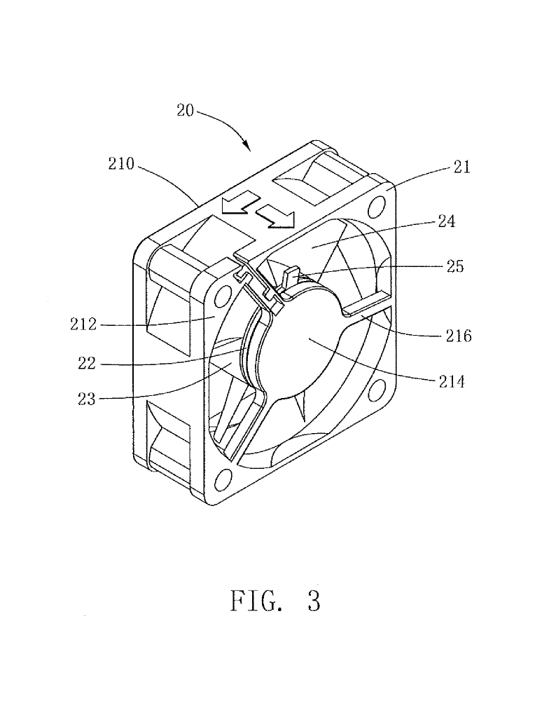

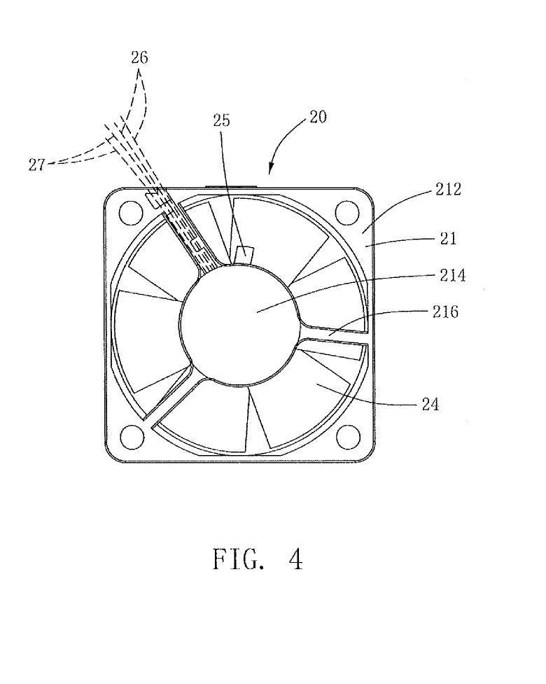

Please refer to FIG. 3 and FIG. 4, FIG. 3 is a structure schematic view of one embodiment of the heat dissipation fan 20 of the present invention, and FIG. 4 is a plan structure schematic view of the heat dissipation fan 20 of the present invention shown in FIG. 3. In one embodiment, the heat dissipation fan 20 of the present invention comprises a frame 21, a fan circuit board 22, a fan motor 23, multiple fan blades 24 and a thermistor 25.

The frame 21 has an air inlet side 210 and an air outlet side 212, and forms a base board 214 on the middle of the air outlet side 212. There disposes multiple support rids 216 on the peripheral of the base board 214 to strengthen the structure of the frame 21. When the heat dissipation fan 20 is mounted in the power device 1, the air inlet side 210 of the frame 21 faces the air inlet opening 12 of the outer case 10 of the power device 1 and is fixed at the air inlet opening 12 of the outer case 10, and the air outlet side 212 of the frame 21 faces the internal of the outer case 10 of the power device 1.

The fan circuit board 22 is mounted on the base board 214 of the frame 21, and the shape of the fan circuit board 22 is generally same as that of the base board 214.

The fan motor 23 is also mounted on the base board 214 of the frame 21 and is electrically connected to the fan circuit board 22. For example, the fan motor 23 is electrically connected to a fan drive circuit of the fan circuit board 22.

The fan blades 24 are mounted on the fan motor 23.

The thermistor 25 is disposed on the fan circuit board 22.

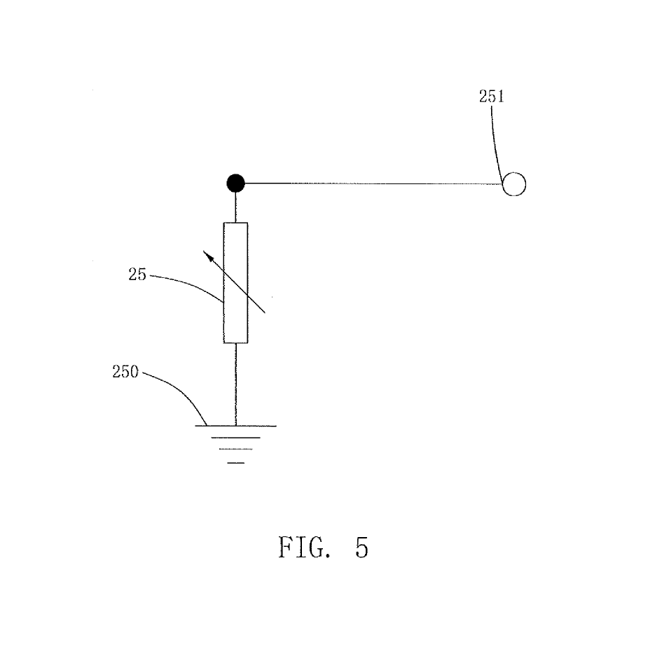

In one embodiment, the thermistor 25 is soldered on the edge of the fan circuit board 22 by a surface mounted technology (SMT), and is located near a power signal-outputting wire 27 of the heat dissipation fan 20, so that it can be convenient for a temperature signal-outputting wire 26 of the thermistor 25 and the power signal-outputting wire 27 to be leaded out at the adjacent positions, and then to be commonly and electrically connected to a complementary connector 21 (shown in FIG. 2) of the control circuit board 30 of the power device I by a connector, whereby the temperature signal can be timely transmitted to the control circuit board 30. The circuit diagram of the thermistor 25 being disposed on the fan circuit board 22 can be seen in FIG. 5. Because the fan drive circuit belongs to the background art, it need not be repeated here. In one embodiment shown as FIG. 5, one end of the thermistor 25 is connected to one ground point 250 on the fan circuit board 22, and the other end thereof is connected to a temperature signal-outputting point 251 of the fan circuit board 22. The grounding point 250 of the thermistor 25 may be shared with a grounding wire of the fan circuit board. In addition, the circuit of the thermistor 25 is not related to the fan drive circuit.

In other embodiments, the thermistor 25 also may be disposed on the fan circuit board 22 by a non-SMT way. For example, it can be soldered on the fan circuit board 22 by a through-hole soldering. Therefore, the present invention does not limit the connection way of the thermistor 25 and the fan circuit board 22.

Additionally, the present invention does not limit the specific location of the thermistor 25 on the heat dissipation fan 20. Namely, the thermistor 25 may be disposed on other locations, but not on the fan circuit board 25.

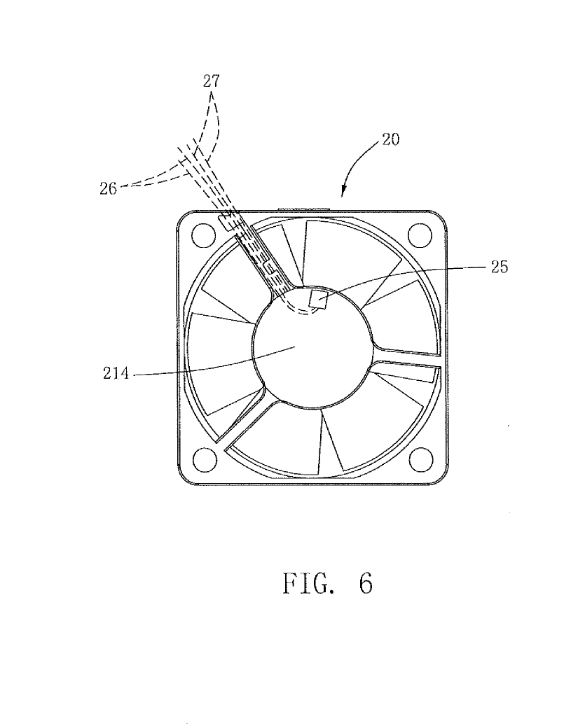

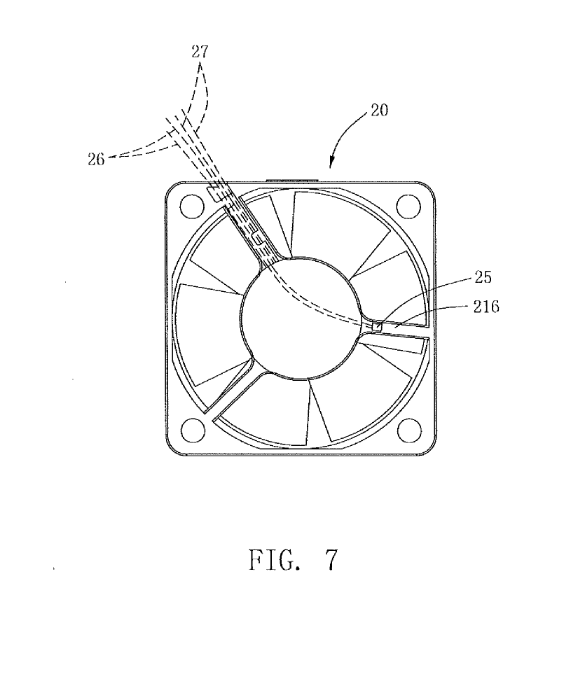

Specifically, please refer to FIG. 6, in another embodiment, the thermistor 25 of the heat dissipation fan 20 of the present invention may be mounted on the frame 21. Preferably, the thermistor 25 may be mounted on the frame 21 near the edge of the fan circuit board 22. In this embodiment, the thermistor 25 is mounted on the base board 214 near the edge of the fan circuit board 22. In another one embodiment, the thermistor 25 of the heat dissipation fan 20 of the present invention also may be mounted on the support rib 216 of the edge of the fan circuit board 22, as shown in FIG. 7.

As shown in FIG. 6 and FIG. 7, when the thermistor 25 is mounted on the frame 21 near the edge of the fan circuit board 22, it can not effect the airflow passage, and the temperature signal-outputting wire 26 leaded out from the thermistor 25 can be convenient to he bonded together with the power signal-outputting wire 27 leaded out from the heat dissipation fan 20 for being commonly connected to the control circuit board 30 of the power device 1.

Furthermore, the thermistor 25 may be mounted on the frame 21 by an adhesive method or by other fixing modes. Accordingly, the present invention does not limit the specific fixing modes of fixing the thermistor 25 on the frame 21.

As described above, because the heat dissipation fan 20 of the present invention disposes the thermistor 25, it not only has a function of providing airflow, but also has a function of sensing temperature. The heat dissipation fan 20 is applied to the power device 1 to save the internal space of the power device 1, and can provide reliable temperature information for the power device 1 to improve the working quality of the power device 1.

In conclusion, although the present invention has been disclosed by above preferred embodiments, above preferred embodiments are not used to limit the present invention. One of ordinary skills in the art also can make all sorts of improvements and amendments within the principles of the present invention. Therefore, the protection scope of the present invention should be based on the scope defined by the appended claims.

1. A heat dissipation fan, which is mounted at an air inlet opening of a power device, comprising:
a frame having an air inlet side and an air outlet side and forming a base board on the middle of the air outlet side;
a fan circuit board being mounted on the base board of the frame;
a fan motor being mounted on the base board of the frame and being electrically connected to the fan circuit board;
multiple fan blades being mounted on the fan motor; and
a thermistor.

2. The heat dissipation fan as claimed in claim 1, wherein the thermistor is disposed on the fan circuit board.

3. The heat dissipation fan as claimed in claim 2, wherein the thermistor is soldered on the edge of the fan circuit board by a surface mounted technology.

4. The heat dissipation fan as claimed in claim 3, wherein the thermistor has a grounding point, which is shared with a grounding wire of the fan circuit board.

5. The heat dissipation fan as claimed in claim 1, wherein the thermistor is disposed on the frame.

6. The heat dissipation fan as claimed in claim 5, wherein the thermistor is located near the edge of the fan circuit board.

7. The heat dissipation fan as claimed in claim 6, wherein the thermistor is mounted on the base board near the edge of the fan circuit board.

8. The heat dissipation fan as claimed in claim 6, wherein the frame also includes multiple support ribs disposed on the peripheral of the base board, and the thermistor is mounted onto one of the support ribs near the edge of the fan circuit board.

9. A power device, comprising:
an outer case having one air inlet opening and multiple air outlet openings;
a heat dissipation fan being mounted in the outer case and located at the air inlet opening of the outer case;
a control circuit board being mounted in the outer case; and
multiple electronic components being mounted in the outer case;
wherein the heat dissipation fan comprises:
a frame having an air inlet side and an air outlet side and forming a base board on the middle of the air outlet side;
a fan circuit board being mounted on the base board of the frame;
a fan motor being mounted on the base board of the frame and being electrically connected to the fan circuit board;
multiple fan blades being mounted on the fan motor; and
a thermistor being capable of providing the nearby temperature information of the air inlet opening for the control circuit board.

10. The power device as claimed in claim 9, wherein the thermistor is disposed on the fan circuit board.

11. The power device as claimed in claim 9, wherein the thermistor is disposed on the frame and near the edge of the fan circuit board.

12. The power device as claimed in claim 10, wherein a temperature signal-outputting wire leaded out from the thermistor and a power signal-outputting wire leaded out from the heat dissipation fan are electrically connected to the control circuit board of the power device.

13. The power device as claimed in claim 9, wherein the air inlet side of the frame of the heat dissipation fan is fixed at the air inlet opening of the outer case, and the air outlet side of the frame thereof faces the internal of the outer case.

14. The power device as claimed in claim 11, wherein a temperature signal-outputting wire leaded out from the thermistor and a power signal-outputting wire leaded out from the heat dissipation fan are electrically connected to the control circuit board of the power device.
